(19) United States
(12) Patent Application Publication
(10) Pub. No.: US 2017/0352609 A1
(43) Pub. Date: Dec. 7, 2017

(54) LEAD FRAME WITH SOLDER SIDEWALLS

(71) Applicant: Texas Instruments Incorporated, Dallas, TX (US)

(72) Inventor: Dan Okamoto, Oita (JP)

(21) Appl. No.: 15/684,620

(22) Filed: Aug. 23, 2017

Related U.S. Application Data
(63) Continuation of application No. 15/075,298, filed on Mar. 21, 2016.

(51) Int. Cl. H01L 23/495; H01L 21/78; H01L 21/48

(52) U.S. Cl. CPC H01L 23/49513; H01L 23/49541; H01L 23/4952; H01L 21/4825; H01L 21/4828; H01L 21/78

(57) ABSTRACT

A leadframe wherein the outer sidewalls of the leadframe that are exposed by sawing during singulation are comprised of greater than 50% solder. A leadframe strip wherein the saw streets and the outer surface of the lead frames are comprised of greater than 50% solder. A method of forming a leadframe strip wherein the saw streets and the outer surface of the lead frames are comprised primarily of solder. A method of forming a leadframe strip wherein the saw streets and the outer surface of the lead frames are comprised entirely of solder.

### CROSS REFERENCE TO RELATED APPLICATIONS

This application is a continuation of Non-provisional patent application Ser. No. 15/075,298, filed Mar. 21, 2016, the entirety of which is hereby incorporated herein by reference.

### FIELD

This disclosure relates to the field of integrated circuits. More particularly, this disclosure relates to lead frames used in integrated circuit packaging.

### BACKGROUND

Semiconductor Small Outline No-Lead (SON) and Quad Flat No-Lead (QFN) devices are typically fabricated by assembling a plurality of integrated circuit (IC) chips on a metallic leadframe strip. The leadframe strip 200 (FIG. 2) is laid out to include for each lead frame 100 (FIG. 1) an IC chip pad 102 (FIG. 1) and coordinated wirebond pads 104. In order to miniaturize the devices and conserve area in the layout of the leadframe strip 200, the layout is commonly designed so that the bondwire pads 104 of one leadframe 100 are connected directly to the respective wirebond pads 104 of the adjacent leadframe 100 by horizontal 202 and vertical 204 saw streets.

The majority of leadframe strips 200 are made of a base metal such as copper or an alloy including copper, and plated with layers of solderable metal, such as a layer of nickel followed by a layer of palladium.

The cross section illustrated in FIG. 3 is taken across a horizontal saw street 204 along the dashed line 206 in FIG. 2. Multiple IC chips 304 are assembled on the leadframe strip 200. After the IC chips 304 are attached to the IC chip pads 102 and electrically connected to the wirebond pads 104 with wirebonds 306, the assembled leadframe strip 300 is encapsulated in a protective plastic compound 308 while areas 310 intended for soldering are not covered by the encapsulation compound 308.

Subsequently, discrete packaged IC chips 400 (FIG. 4) are singulated from the assembled leadframe strip 300 by cutting through the encapsulating compound 308 and the plated metal saw streets, 202 and 204, with a saw. As a consequence of the sawing step, the wirebond pads 104 have a side surface 410 (FIG. 4A) where the base metal is exposed by the sawing. Finally, the discrete packaged IC chips 400 are assembled on a circuit board 402 by solder-connecting 406 the non-covered areas 3140 to metallic pads 404 on the circuit board 402 as shown in FIG. 4C.

### SUMMARY

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to a more detailed description that is presented later.

IC chips are attached to leadframe strips and encapsulated in a protective plastic compound. Individual IC chips are then singulated by sawing them apart along the saw streets. During the singulation process the sawing exposes unprotected leadframe metal which may oxidize and prevent solder from wetting the surface and forming a strong bond when the IC chips are attached by soldering to a printed circuit board.

A leadframe wherein the outer sidewalls of the leadframe that are exposed by sawing during singulation are comprised of greater than 50% solder. A leadframe strip wherein the saw streets and the outer surface of the lead frames are comprised of greater than 50% solder. A method of forming a leadframe strip wherein the saw streets and the outer surface of the lead frames are comprised primarily of solder. A method of forming a leadframe strip wherein the saw streets and the outer surface of the lead frames are comprised entirely of solder.

### DESCRIPTION OF THE VIEWS OF THE DRAWINGS

FIG. 1 (Prior art) is a plan view of a leadframe.

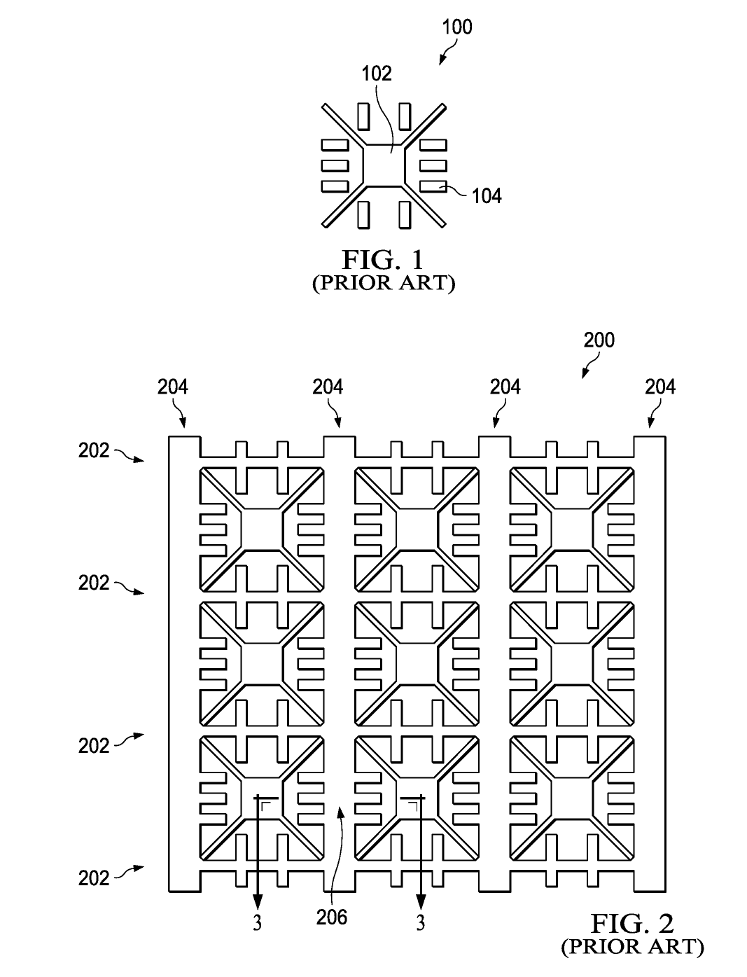

FIG. 2 (Prior art) is a plan view of a leadframe strip.

FIG. 3 (Prior art) is a cross-section of packaged IC chips on a leadframe strip.

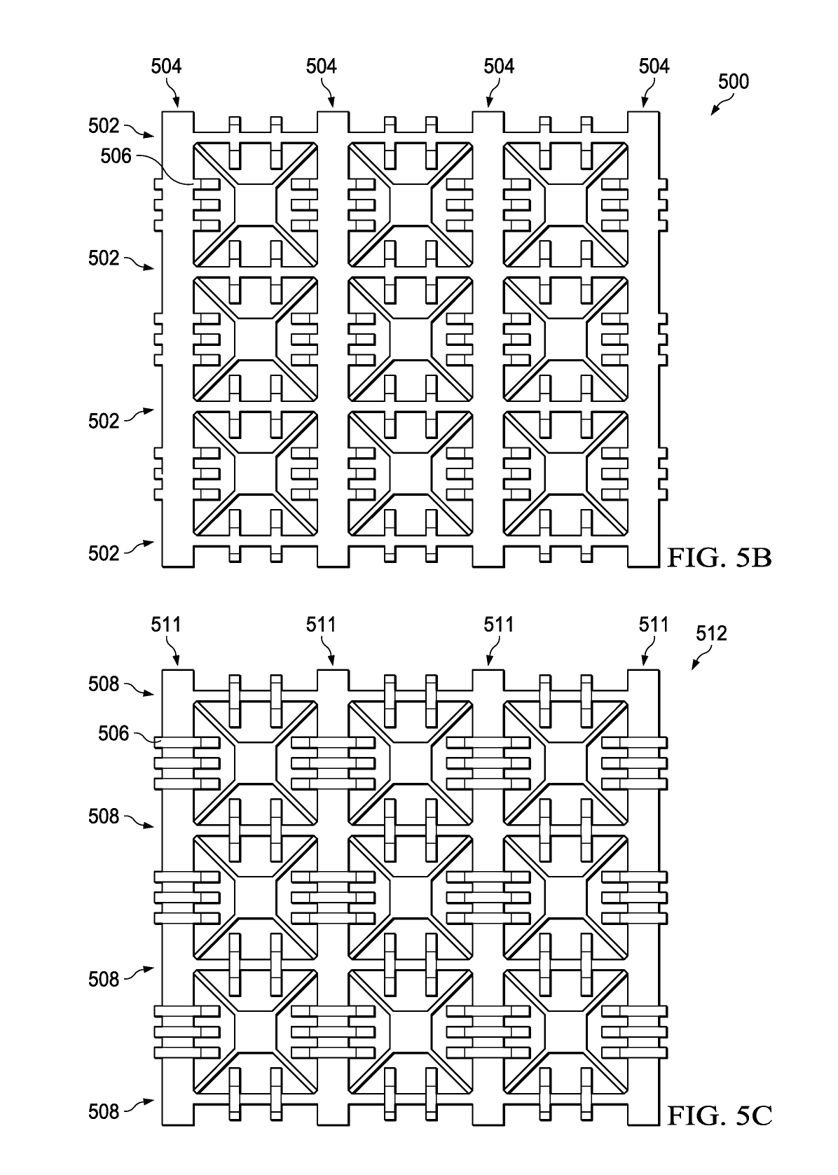

FIGS. 4A, 4B, and 4C describe the attachment of a packaged IC to a circuit board by soldering.

FIG. 5A describe a leadframe formed according to embodiments.

FIGS. 5B, and 5C describe lead frame strips formed according to embodiments.

FIGS. 6A and 6B are cross sections illustrating a leadframe strip formed according to embodiments.

FIGS. 7A and 7B are cross sections illustrating a leadframe strip formed according to embodiments.

FIGS. 8A through 8L are cross sections of the lead frame strip in FIG. 6A depicted in successive stages of fabrication.

FIGS. 9A through 9L are cross sections of the lead frame strip in FIG. 7A depicted in successive stages of fabrication.

### DETAILED DESCRIPTION OF EXAMPLE EMBODIMENTS

Embodiments of the disclosure are described with reference to the attached figures. The figures are not drawn to scale and they are provided merely to illustrate the disclosure. Several aspects of the embodiments are described below with reference to example applications for illustration. It should be understood that numerous specific details, relationships, and methods are set forth to provide an understanding of the disclosure. One skilled in the relevant art, however, will readily recognize that the disclosure can be practiced without one or more of the specific details or with other methods. In other instances, well-known structures or operations are not shown in detail to avoid obscuring the disclosure. The embodiments are not limited by the illustrated ordering of acts or events, as some acts may occur in different orders and/or concurrently with other acts or events. Furthermore, not all illustrated acts or events are required to implement a methodology in accordance with the present disclosure.

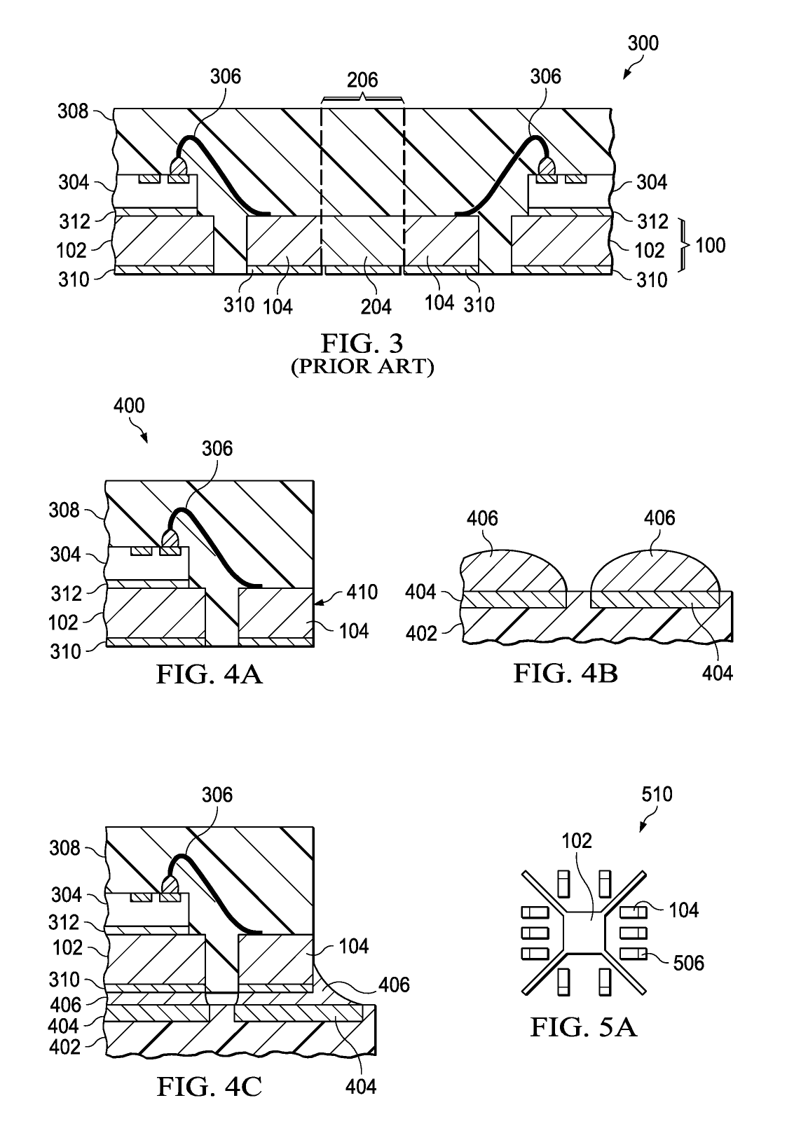

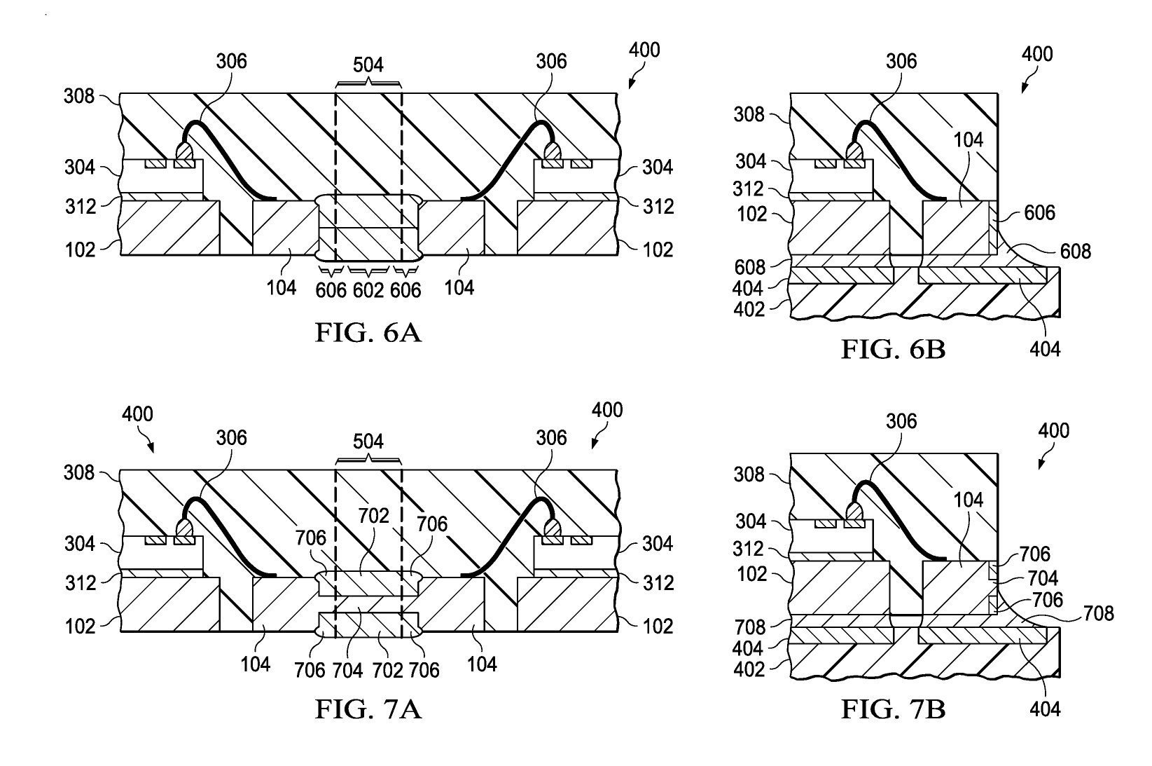

Discrete packaged IC chips 400 (FIG. 4A) are singulated from the assembled leadframe strip 300 by cutting through the encapsulated compound 308 and the plated metal saw streets, 202 and 204 (FIG. 2), with a saw. On conventional leadframe strips, as a consequence of the sawing step, the wirebond pads 104 have a side surface 410 (FIG. 4A) where the base metal is exposed. The saw-exposed base metal becomes oxidized upon exposure to air. Solder paste applied prior to soldering the packaged IC chip 400 to the circuit board 402 is sometimes insufficient to remove the oxidation. When this occurs, the solder 406 cannot wet the sidewall of the wirebond pad 104 and does not form a solder-bond to the vertical side of the packaged IC chip 400. This may result in a weak bond between the packaged IC chip 400 and the circuit board 420 which may result in the failure of an electrical connection between the packaged IC chip 400 and the circuit board 402 or may result in the delamination of the packaged IC chip 400 from the circuit board 402. This is especially problematic when the failure occurs as a result of mechanical stress on a circuit board 402 during use the field.

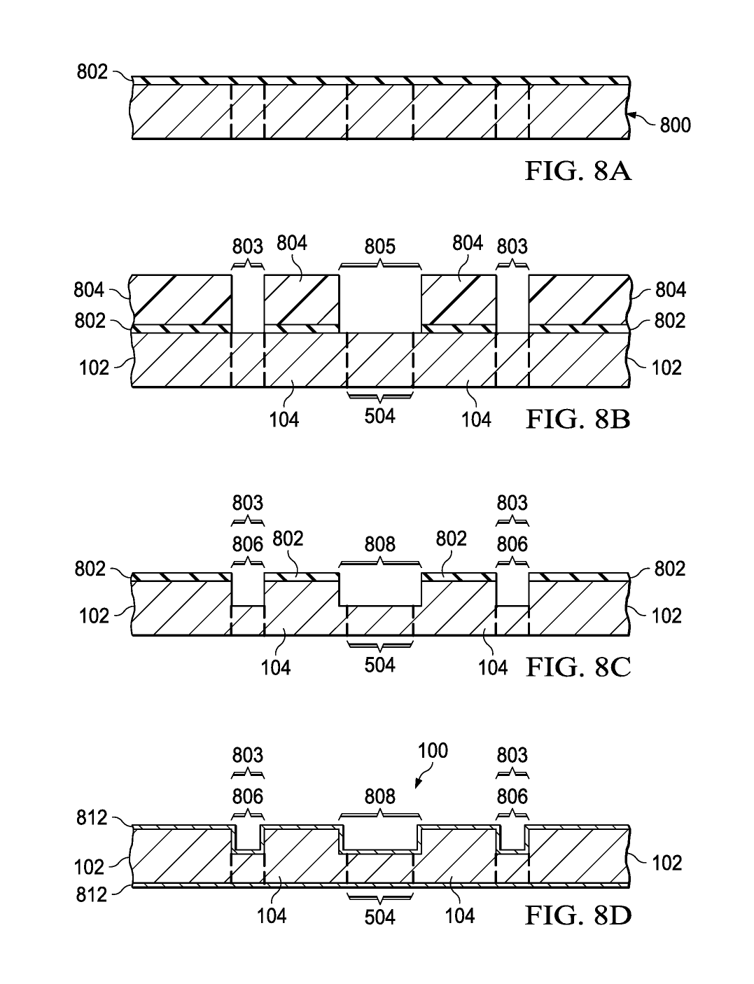

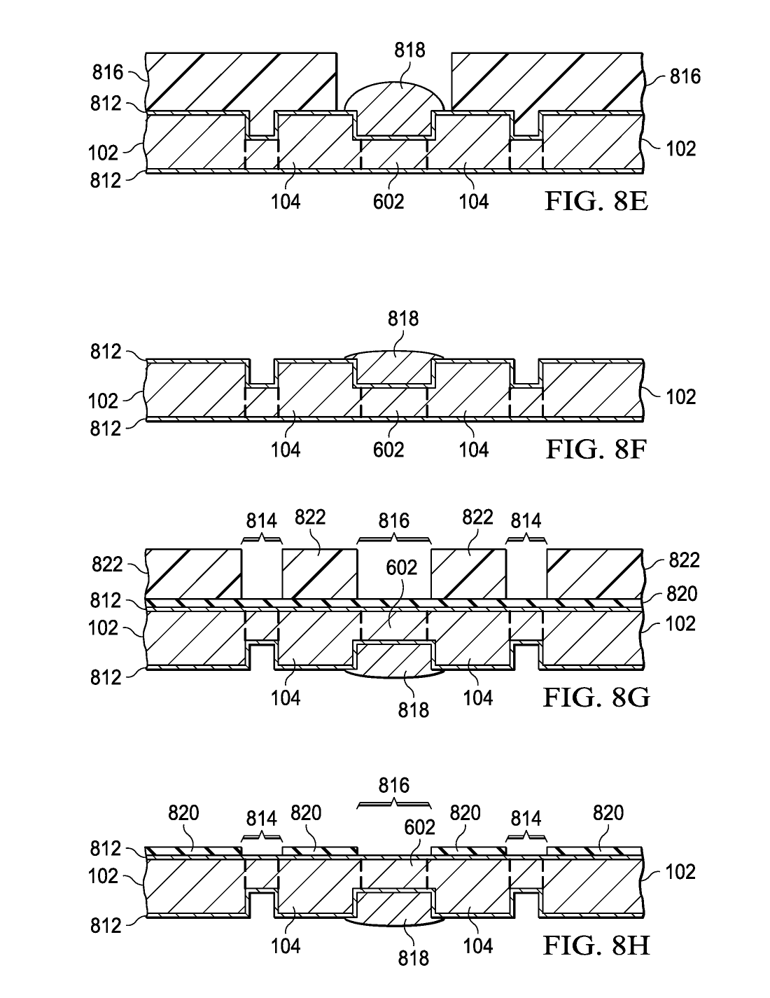

An embodiment leadframe 510 that resolves the problem of exposed base metal on the sidewalls of the bondwire pads 104 as a result of sawing is illustrated in FIG. 5A. In the embodiment the base metal on the sidewalls of the bondwire pads 104 that are exposed by sawing is replaced with solder 506.

A first example lead frame strip 500 in FIG. 5B, is comprised of a plurality of embodiment leadframes 510 connected together with horizontal 502 and vertical 504 saw streets. In this embodiment all or most of the base metal in the horizontal 502 and vertical 504 saw streets is replaced with solder 506.

A second example lead frame strip 512 in FIG. 5C, is comprised of a plurality of embodiment leadframes 510 connected together with horizontal 508 and vertical 510 saw streets. In this embodiment all or most of the base metal in the regions of the horizontal 508 and vertical 510 saw streets between the bondwire pads 104 is replaced with solder 506. The remainder of the saw street area 508 and 510 that is not connected to wirebond pads 104 remains base metal.

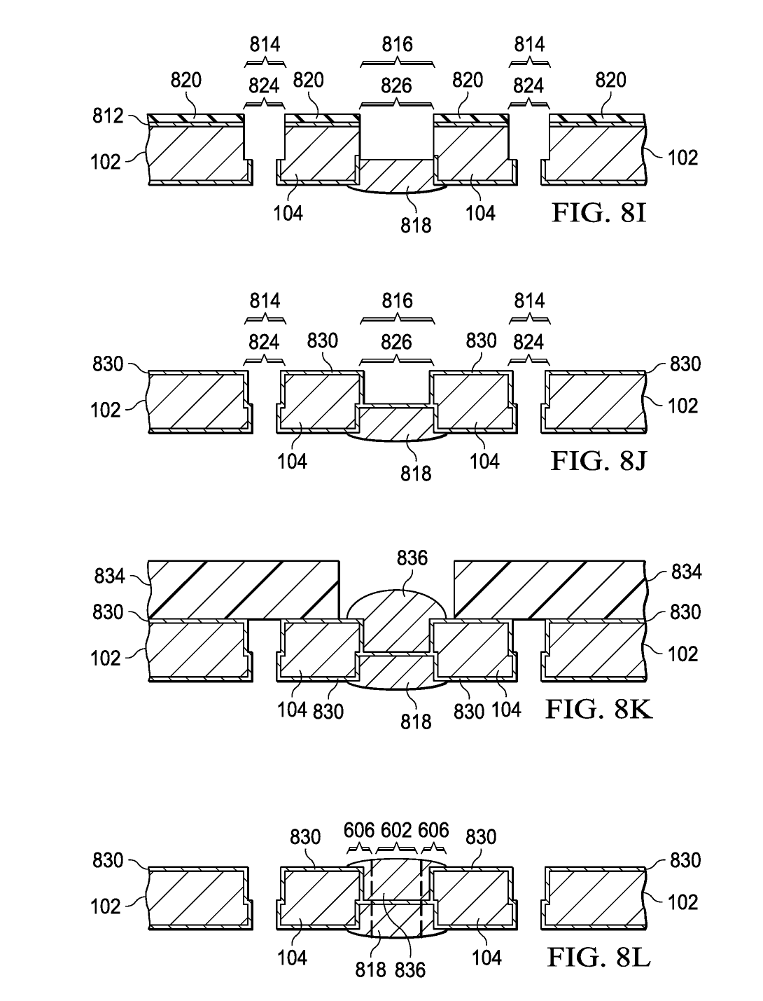

FIG. 6A illustrates an example where all the base metal in the saw streets between the wirebond pads 104 is replaced with solder 602. After sawing, as shown in FIG. 6B, no base metal is exposed on the sidewalls of the wirebond pads 104. The base metal on the sidewalls of the wirebond pads 104 is replaced with solder 606. This solder sidewall 606 forms a strong bond with the solder 608 used to attach the IC chip 400 to the circuit board 402.

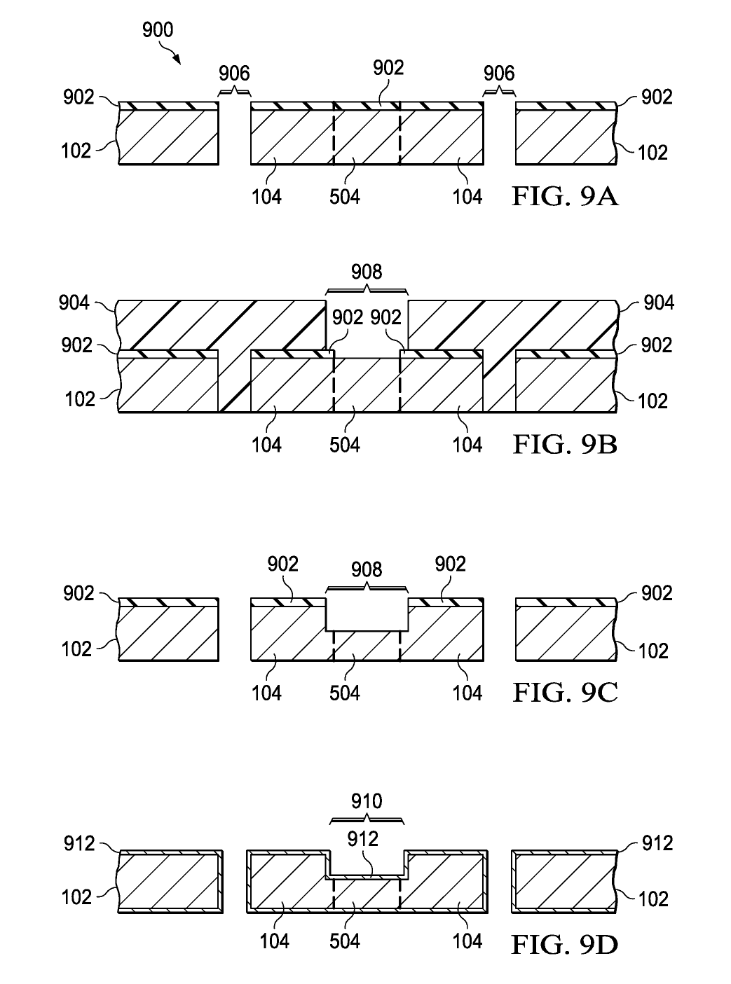

FIG. 7A illustrates an example where a majority of the base metal in the saw streets between the wirebond pads 104 is replaced with solder 702. After sawing, as shown in FIG. 7B, only a small amount of the base metal 704 is exposed on the sidewalls of the wirebond pads 104. Over 50% of the base metal on the sidewalls of the wirebond pads 104 is replaced with solder 706. This solder on the sidewall 706 forms a strong bond with the solder 708 used to attach the IC chip 400 to the circuit board 402.

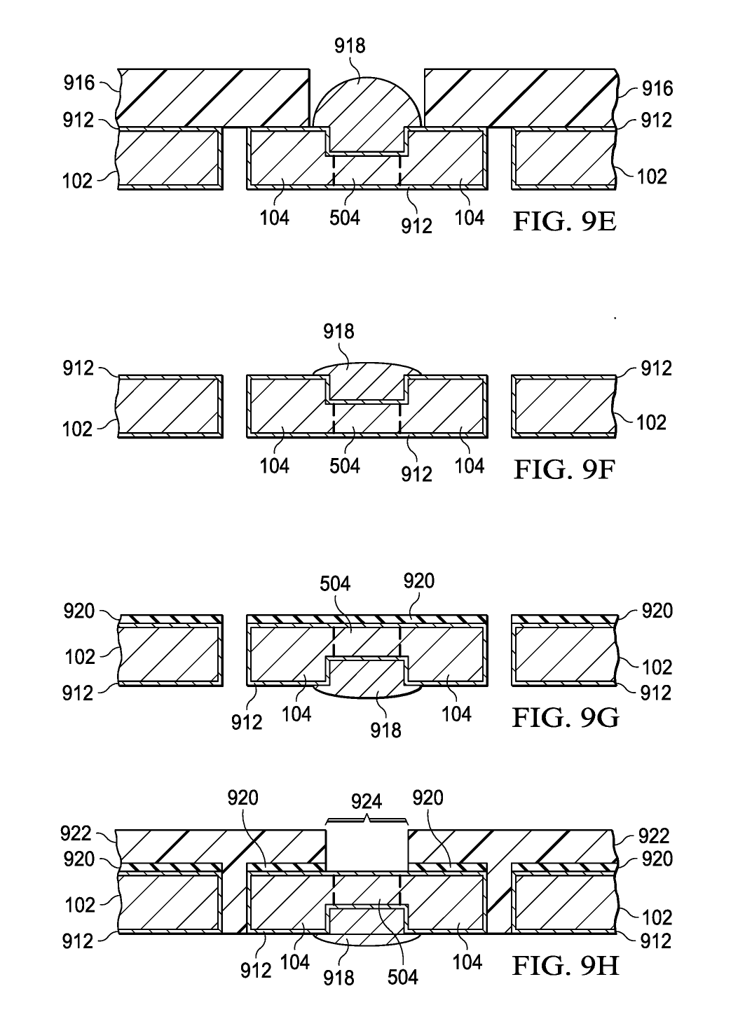

A method for forming the embodiment leadframe strip in cross sections in FIGS. 6A and 6B is described in the cross sections illustrating the major processing steps in FIGS. 8A through 8L.

FIG. 8A shows a metal strip 800 (lead frame strip) covered with a protective dry film coating 802. The metal strip 800 used in leadframe strip manufacture typically is formed of copper or a copper alloy. The protective dry film coating may be photoresist or electrodeposited polyimide for example.

In FIG. 8B a photo resist pattern 804 is formed with openings 803 between the IC chip pad 102 and the bondwire pad 104 areas and also an opening 805 over and slightly wider than the saw street 504. The opening 805 over the saw street 504 exposes the entire width of the saw street 504 and also a small area of the bondwire pads 104 that are attached to the saw street 504. The openings 808 over the saw street 504 may be in the range of about 0.06 mm to about 0.2 mm wider than the saw street 504. In an example embodiment the opening 808 is 0.06 mm wider than the saw street 504.

To form the leadframe shown in FIG. 5B, the photoresist pattern openings 803 and 805 over the saw streets 504 opens the entire saw streets 504.

To form the lead frame shown in FIG. 5C, the photoresist pattern openings 805 over the saw streets 504 opens the street regions between bondwire pads 104 on adjacent leadframes 510 only. The remainder of the saw street areas 504 remains base metal.

The dry film coating 802 is etched from the open areas, 803 and 805, exposing the base metal on the leadframe strip.

In FIG. 8C, the photo resist pattern 804 is removed and the base metal is etched from the open areas in the dry film coating. The base metal is etched approximately half way 806 through the lead frame strip 800 between the IC chip pad 102 and the wirebond pad 104 areas and is also etched approximately half way through the saw streets 504 and exposed regions of the wirebond pads 104 adjacent to the saw streets 504 forming a front side saw street trench 808.

In FIG. 8D the dry film coating 802 is removed and a thinfilm 812 of a metal such as nickel plus palladium or nickel plus palladium plus gold is deposited or electroplated onto the exposed surfaces of the leadframe strip 800 to enhance solderability.

In FIG. 8E, a front side screen printing mask 816 with an opening slightly wider than the front side half etched saw street 808 is centered over the first half etched saw street 808. Solder paste 818 is then screen printed onto the leadframe strip 800 completely filling and slightly over filling the front side saw street trench 808.

The front side screen printing mask 816 is then removed and the solder paste 818 is reflowed as shown in FIG. 8F to fill the front side saw street trench 808 and to form solder sidewalls 606 on the wirebond pads. The base metal in the front side saw street trench 808 and also the base metal in the half etched region of the wirebond pads 104 adjacent to the saw street 504 in this embodiment is replaced with solder.

Referring now to FIG. 8G, the leadframe strip 800 is turned upside down and a second protective dry film coating 820 is applied to the backside of the leadframe strip 800. A second photoresist pattern 822 with openings 814 exposing the base metal between the IC chip pad 102 and the wirebond pad 104 areas and also openings 816 over and slightly wider than the saw street 504 is formed on the backside of the leadframe strip 800. The openings 816 over the saw street 504 may be in the range of about 0.06 mm to about 0.2 mm wider than the saw street 504. In an example embodiment the opening 816 is 0.06 mm wider than the saw street 504.

To form the leadframe shown in FIG. 5B, the photoresist pattern openings 816 over the saw streets 504 opens the entire saw streets.

To form the lead frame shown in FIG. 5C, the photoresist pattern openings 816 over the saw streets 504 opens only the saw street regions between bondwire pads 104 on adjacent leadframes 510.

The dry film coating 820 is etched from the openings between the IC chip pad 102 and the wirebond pad 104 areas and also the open regions over the saw street 504 and the exposed wirebond pad 104 regions attached to the saw streets 504.

FIG. 8H shows the leadframe strip 800 after the second protective dry film coating 820 is etched and the second photo resist pattern 822 is removed.

In FIG. 8I the base metal of the leadframe strip 800 is etched where exposed by the openings in the second protective dry film coating 820. The openings 824 between the IC chip pads 102 and the wirebond pads 104 are etched so that these openings 824 join with the half etched openings 806 that were previously etched from the front side of the leadframe strip 800. This removes all the base metal from between and electrically isolates the IC chip pads 102 from the wirebond pads 104. The base metal is also etched from the saw streets 504 and the exposed regions of the wirebond pads 104 adjacent to the saw streets 504 stopping on the reflowed solder 818 filling the front side saw street trench 808.

In FIG. 8J the second dry film coating 820 is removed and a second metal 830 such as nickel plus palladium or nickel plus palladium plus gold is deposited or electroplated onto the exposed surfaces of the leadframe strip 800 to enhance solderability.

In FIG. 8K, a backside screen printing mask 834 with an opening over and slightly larger than the backside saw street trench 826 is placed on the backside of the lead frame strip 800. Solder paste 836 is then screen printed onto the leadframe strip 800 to fill and slightly overfill the backside saw street trench 826.

The backside screen printing mask 834 is then removed and the solder paste 836 is reflowed as shown in FIG. 8L to completely fill the saw street 602 and also to fill an outer portion 606 of the wirebond pads 104 with reflowed solder 836. In this embodiment the base metal in the saw street 504 is replaced completely with solder 602. In addition, the base metal in the sidewalls of the wirebond pads 104 removed by sawing is also completely replaced with solder 606.

As discussed previously, when the packaged IC chips 400 are singulated by sawing using this embodiment no base metal is exposed. The sidewalls on the packaged IC chips 400 that are formed as the result of sawing during singulation are composed entirely of solder 606. As illustrated in FIG. 6B, using this embodiment, strong solder bonds are formed to the sidewalls of the packaged IC chip 400 during attachment to an integrated circuit board 402 by soldering 608.

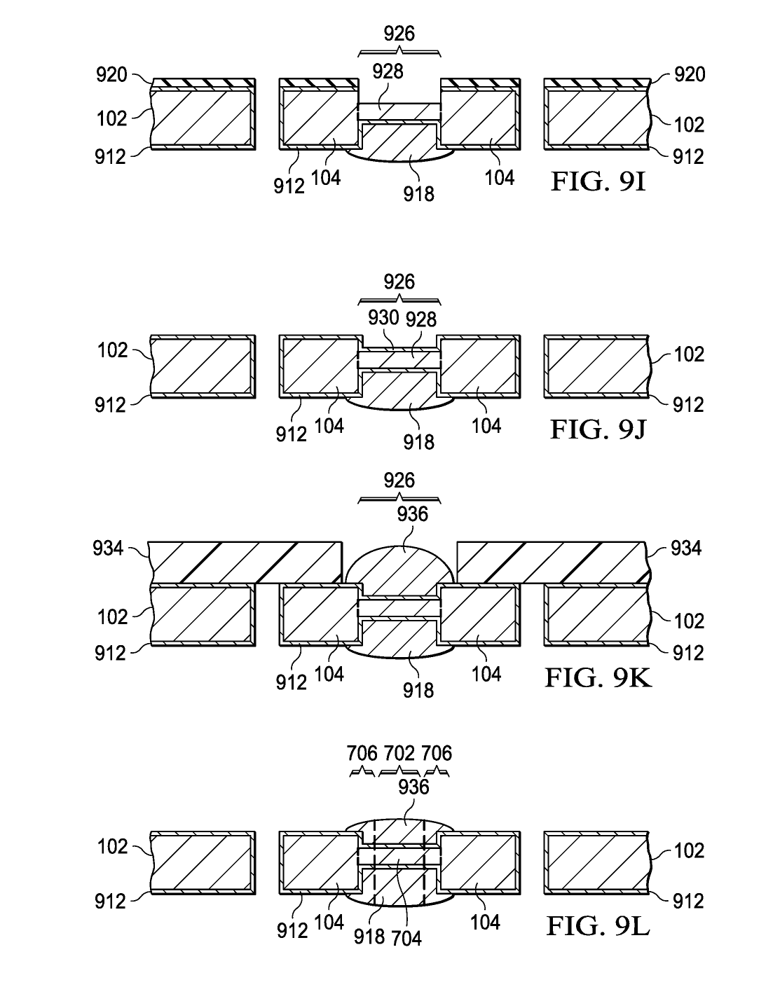

A method for forming second embodiment leadframe strips shown in FIG. 7B, is described in the cross sections illustrating the major processing steps in FIGS. 9A through 9L.

FIG. 9A shows a metal leadframe strip 900 covered with a protective dry film coating 902. Openings 906 etched through the lead frame strip 900 electrically isolate the IC chip pads 102 from the wirebond pads 104.

In FIG. 9B a photo resist pattern 904 is formed with openings 908 over and slightly wider than the saw street 504. A small portion of the wirebond pads 104 adjacent to the saw street 504 is exposed. The dry film coating 902 is etched from the open area 908. The openings 908 over the saw street 504 may be in the range of about 0.06 mm to about 0.2 mm wider than the saw street 504. In an example embodiment the opening 816 is 0.06 mm wider than the saw street 504.

To form the leadframe shown in FIG. 5B, the photoresist pattern openings 908 over the saw streets opens the entire saw streets.

To form the lead frame shown in FIG. 5C, the photoresist pattern openings 908 over the saw streets 504 opens only the saw street regions between bondwire pads 104 on adjacent leadframes 510.

In FIG. 9C, the photo resist pattern 904 is removed and base metal is partially etched from the saw street 504 and the exposed regions of the wirebond pads to form a front side saw street trench 910. The thickness of the base metal removed in this embodiment is less than half the thickness of the leadframe strip 900 but more than one fourth the thickness.

In FIG. 9D the dry film coating 902 is removed and a metal film 912 such as nickel plus palladium or nickel plus palladium plus gold is deposited or electroplated onto the exposed surfaces of the leadframe strip 900 to enhance solderability.

In FIG. 9E, a front side screen printing mask 916 with an opening over the front side saw street trench 910 is placed on the front side of the lead frame strip 900. Solder paste 918 is then screen printed onto the leadframe strip 900 to completely fill and slightly overfill the front side saw street trench 910.

The front side screen printing mask 916 is then removed and the solder paste 918 is reflowed as shown in FIG. 9F filling the front side saw street trench 702 and filling with solder 918 the etched regions of the wirebond pads 104 adjacent to the saw street 706 The base metal in the front side saw street trenches 910 is replaced with solder 702. In addition, the base metal in the half etched regions of the wirebond pads 104 adjacent to the saw street 504 are replaced with solder 706.

Referring now to FIG. 9G, the leadframe strip 900 is turned upside down and a second protective dry film coating 920 is applied to the backside of the leadframe strip 900.

In FIG. 9H, a second photoresist pattern 922 with an opening 924 over and slightly wider than the saw street 504 is formed. A small portion of the wirebond pads 104 adjacent to the saw street 504 are also exposed.

The openings 924 over the saw street 504 may be in the range of about 0.06 mm to about 0.2 mm wider than the saw street 504. In an example embodiment the opening 816 is 0.06 mm wider than the saw street 504.

To form the leadframe shown in FIG. 5B, the photoresist pattern openings 924 over the saw streets opens the entire saw streets.

To form the lead frame shown in FIG. 5C, the photoresist pattern openings 924 over the saw streets 504 opens only the saw street regions between bondwire pads 104 on adjacent leadframes 510.

The dry film coating 920 is then etched from the open area 924 as shown in FIG. 9H.

In FIG. 9I the base metal of the leadframe strip 900 is partially etched from the saw street 504 and also etched from the exposed regions of the wirebond pads 104 that are attached to the saw street 504. The thickness of the base metal removed is less than half the thickness of the leadframe strip 900 but more than one fourth the thickness. This forms a backside saw street trench 926 and leaves a strip of base metal 928 across the saw street 504. This strip of base metal 928 connects the wirebond pads 104 of a first lead frame 100 to wirebond pads 104 of a second lead frame 100 across the saw street 504. This strip of metal 928 may add reinforcement and rigidity to the leadframe strip 500.

In FIG. 9J the second dry film coating 920 is removed and a second metal film 930 such as nickel plus palladium or nickel plus palladium plus gold is deposited or electroplated onto the exposed surfaces of the leadframe strip 900 to enhance solderability.

In FIG. 9K, a backside screen printing mask 934 with an opening slightly larger than the backside saw street trench 926 is placed on the backside of the lead frame strip 900. Solder paste 936 is then screen printed onto the leadframe strip 900 filling and slightly overfilling the backside saw street trench 926.

The backside screen printing mask 934 is then removed and the solder paste 936 is reflowed as shown in FIG. 9L filling the backside saw street trench 926 and also to filling the partially etched wirebond pads with reflowed solder 936. In this embodiment more than half the base metal in the saw street 504 is replaced with solder 702. In addition, more than half the sidewall of the wirebond pads 104 exposed during singulation by sawing is replaced with solder 706 leaving only a small portion of base metal 702 exposed on the sidewall.

As discussed previously, when the packaged IC chips 400 are singulated by sawing with this embodiment less than half the exposed sidewall is base metal. As illustrated in FIG. 7B, by replacing more than of the base metal that is exposed on the sidewalls of the wirebond pads 104 by sawing with solder 706, a strong reliable bond may be formed when the packaged IC chip 400 is soldered to the integrated circuit board 402.

While various embodiments of the present disclosure have been described above, it should be understood that they have been presented by way of example only and not limitation. Numerous changes to the disclosed embodiments can be made in accordance with the disclosure herein without departing from the spirit or scope of the disclosure. Thus, the breadth and scope of the present disclosure should not be limited by any of the above described embodiments. Rather, the scope of the disclosure should be defined in accordance with the following claims and their equivalents.

What is claimed is:

1. An integrated circuit (IC) package comprising:
a lead frame including a chip pad and a plurality of wire bond pads;
an IC chip on the chip pad and electrically connected via wire bond to a horizontal surface of at least one of the plurality of wire bond pads; and
a vertical surface of the at least one of the plurality of wire bond pads exposed from the IC package, the vertical surface in a vertical direction, the vertical surface including a base metal of the wire bond pad exposed between solder portions in the vertical direction, and surfaces of the base metal and the solder being coplanar.

2. The IC package of claim 1, wherein the vertical surface includes solder portions on a top edge and a bottom edge with base metal exposed in between, a portion of the top edge coplanar with the horizontal surface and a portion of the bottom edge coplanar with a surface of the IC package opposite and parallel to the horizontal surface.

3. The IC package of claim 1 further comprising a circuit board mechanically and electrically attached to the IC package.

4. The IC package of claim 1, wherein the base metal is one of a copper and a copper alloy.

5. The IC package of claim 1, wherein the IC package is a Quad Flat No-Lead IC package.

6. The IC package of claim 2, wherein the surface of the IC package opposite and parallel to the horizontal surface includes the base metal and a solder exposed from the IC package.

7. The IC package of claim 1 further comprising a plastic compound covering portions of the IC chip, the chip pad and the plurality of wire bond pads.

8. The IC package of claim 7, wherein the plastic compound includes a surface coplanar with the vertical surface.

9. An integrated circuit (IC) package comprising:
a lead frame including a chip pad and a plurality of wire bond pads;
an IC chip on the chip pad and electrically connected via wire bond to a surface of at least one of the plurality of wire bond pads; and
a sidewall of the at least one of the plurality of wire bond pads exposed from the IC package, the sidewall including a base metal of the wire bond pad between solder portions, wherein surfaces of the base metal and the solder comprise an entire portion of the sidewall, and wherein the base metal and the solder are coplanar.

10. The IC package of claim 9, wherein the solder portions include a rectangular cross sectional shape having angled edges.

11. The IC package of claim 9 further comprising a plastic compound covering portions of the IC chip, the chip pad, and the plurality of wire bond pads.

12. The IC package of claim 9, wherein the surface of at least one of the plurality of wire bond pads includes the base metal.

13. An integrated circuit (IC) package comprising:
a lead frame including a chip pad and a plurality of wire bond pads;
an IC chip on the chip pad and electrically connected to a first surface of at least one of the plurality of wire bond pads; and
a second surface of the at least one of the plurality of wire bond pads exposed from the IC package, the second surface being at an angle with the first surface, the second surface including a base metal of the wire bond pad exposed between solder portions in a first direction along the second surface, and surfaces of the base metal and the solder being coplanar.

14. The IC package of claim 13, wherein the IC chip is electrically connected to the first surface via wire bonds.

15. The IC package of claim 13, wherein the base metal is one of a copper and a copper alloy.

16. The IC package of claim 13, wherein the IC package is a Quad Flat No-Lead IC package.

17. The IC package of claim 13 further comprising a plastic compound covering portions of the IC chip, the chip pad and the plurality of wire bond pads.

18. The IC package of claim 13, wherein a portion of the chip pad is exposed from the IC package.
